(19) United States
(12) Patent Application Publication
(10) Pub. No.: US 2022/0051709 A1
(43) Pub. Date: Feb. 17, 2022

(54) ROW-WISE TRACKING OF REFERENCE GENERATION FOR MEMORY DEVICES

(71) Applicant: GLOBALFOUNDRIES U.S. INC., SANTA CLARA, CA (US)

(72) Inventors: Akhilesh R. JAISWAL, West Lafayette, IN (US); Bipul C. PAUL, Mechanicville, NY (US)

(21) Appl. No.: 16/990,441

(22) Filed: Aug. 11, 2020

(51) Int. Cl. G11C 11/16; G11C 5/02

(52) U.S. Cl. CPC G11C 11/1675; G11C 11/1673; G11C 5/025; G11C 11/1657; G11C 11/1655

(57) ABSTRACT

The present disclosure relates to a structure including a plurality of magnetic random access memory (MRAM) bitcells including a first circuit and a second circuit, the second circuit being connected to a same wordline as the first circuit such that the second circuit is configured as a parallel series connection to generate a reference resistance value for sensing.

### FIELD OF THE INVENTION

The present disclosure relates to reference generation, and more particularly, to a circuit and a method for row-wise tracking of reference generation for memory devices and methods of operation.

### BACKGROUND

Memory devices are employed as internal storage areas in a computer or other electronic equipment. One specific type of memory used to store data in a computer is random access memory (RAM). RAM is typically used as the major on-chip as well as off-chip storage unit in a computing system, and is generally volatile in that once power is turned off, all data stored in the RAM is lost.

Resistive nonvolatile memory (NVM) structures, are being considered by circuit designers for on-chip memory arrays because of advantages including high speed, low power consumption, non-volatility, and low area consumption. These NVM structures can include spin transfer torque-magnetic tunnel junction magnetic random access memory (STT-MTJ MRAM), Spin-orbit-torque MRAM (SOT-MRAM), and voltage controlled magnetic anisotropy magnetic tunnel junction magnetic random access memory (VCMA-MTJ MRAM).

A MRAM structure includes an array of MRAM cells (e.g., STT-MTJ MRAM cells) arranged in columns and rows. A MRAM cell includes a single field effect transistor (FET) (e.g., an n-type field effect transistor (NFET)), a single variable resistor, and a single magnetic tunnel junction (MTJ). The FET and MTJ are connected in series between a source line and a bitline with a gate of the FET controlled by a state of a wordline. A MTJ is a back end of the line (BEOL) multi-layer structure, which includes a fixed ferromagnetic layer (i.e., a pinned layer) and a switchable ferromagnetic layer (i.e., a free layer) separated by a thin dielectric layer (e.g., a thin oxide layer).

In known MRAM circuits, sensing can be difficult due to limited tunnel magnetoresistance (TMR). Further, in known MRAM circuits, a sensing margin can be highly dependent on a spread and variability of a reference resistance.

### SUMMARY

In an aspect of the disclosure, a structure includes a plurality of magnetic random access memory (MRAM) bitcells including a first circuit and a second circuit, the second circuit being connected to a same wordline as the first circuit such that the second circuit is configured as a parallel series connection to generate a reference resistance value for sensing.

In another aspect of the disclosure, a circuit includes a reference bit circuit which includes a plurality of first columns for generating a reference resistance value, and a read/write array circuit which includes a plurality of second columns for performing at least one of a read operation and a write operation.

In another aspect of the disclosure, a method includes programming a plurality of reference bits in a reference bit circuit which is connected to a read/write array circuit, and sensing the plurality of reference bits using at least one sense amplifier which is connected to an output of the reference bit circuit.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a magnetic random access memory (MRAM) structure which includes a reference bit circuit in accordance with aspects of the present disclosure.

FIG. 2A shows the reference bit circuit of the MRAM structure in accordance with aspects of the present disclosure.

FIG. 2B shows a representation of the reference bit circuit of the MRAM structure in accordance with aspects of the present disclosure.

FIG. 3 shows programming of the reference bit circuit in a first cycle of the MRAM structure in accordance with aspects of the present disclosure.

FIG. 4 shows programming of the reference bit circuit in a second cycle of the MRAM structure in accordance with aspects of the present disclosure.

FIG. 5A shows a read operation of the reference bit circuit of the MRAM structure in accordance with aspects of the present disclosure.

FIG. 5B shows a representation of the read operation of the reference bit circuit of the MRAM structure in accordance with aspects of the present disclosure.

FIG. 6A shows another plurality of reference bit circuits in accordance with aspects of the present disclosure.

FIG. 6B shows a representation of the another plurality of reference bit circuits in accordance with aspects of the present disclosure.

### DETAILED DESCRIPTION

The present disclosure relates to reference generation, and more particularly, to a circuit and a method for row-wise tracking of reference generation for memory devices and methods of operation. More specifically, the memory device is a magnetic random access memory (MRAM). In embodiments, the memory device can generate a reference signal from a same wordline as a read access wordline. Advantageously, the memory device described herein provides accurate midpoint reference generation and row-wise reference tracking, amongst other advantages described herein.

In known MRAM circuits, sensing can be difficult due to limited tunnel magnetoresistance (TMR). Further, in known MRAM circuits, a sensing margin can be highly dependent on a spread and variability of a reference resistance. Therefore, there is a need to reduce reference bit variability. In order to reduce reference bit variability, known systems use a combination of magnetic tunnel junctions (MTJs), such as four (4) MTJs or 16 MTJs, or a dedicated sub-array outside an active array as a reference signal.

In comparison to known systems, the present disclosure generates a reference bit on a same active wordline as a read access wordline. The present disclosure also uses a parallel-series connection of MTJs inside an active array. Accordingly and advantageously, by implementing the circuit and method described herein, the present disclosure provides an accurate midpoint reference generation (i.e., (Rp+Rap)/2), is compatible with midpoint sensing, uses minimal control circuitry, has row wise reference tracking, reduces sigma of the midpoint sensing by approximately 50%, and accommodates redundancy.

By way of more specific example, the memory device (e.g., structure) comprises a plurality of MRAM bitcells forming a parallel series connection to form an effective reference resistance for sensing. In embodiments, the structure uses additional columns in an MRAM array, wherein a true bitcell used for reference generation can be identical to an active bitcell. Moreover, the memory device can use peripheral circuits such as transistor switches or logic gates circuit for writing into the MTJ structure. In addition, the structure includes a circuit to generate reference resistance for sensing, wherein the reference bits can be programmed at the same time that the array is being written. Further, in the circuit to generate reference resistance for sensing, a read control circuitry can be used to generate the reference resistance during the read operation.

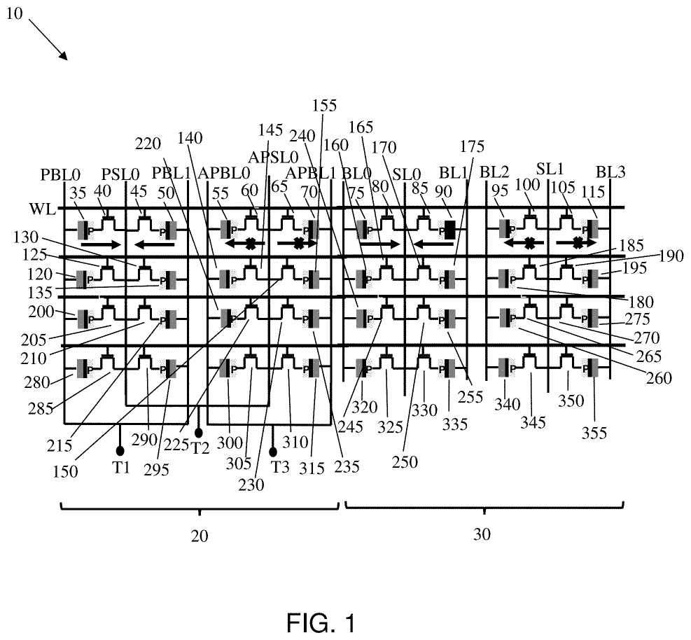

FIG. 1 shows a magnetic random access memory (MRAM) structure which includes a reference bit circuit in accordance with aspects of the present disclosure. In FIG. 1, a MRAM structure 10 includes a reference bit circuit 20 and a read/write array 30. In this embodiments, the reference bit circuit 20 uses the same wordline WL as the read/write array 30. The reference bit circuit 20 includes MTJs 35, 50, 55, and 70 which are connected to respective bitlines PBL0, PBL1, APBL0, and APBL1 in a first row. The first row of the reference bit circuit 20 also includes NFETs 40, 45, 60, and 65 which are connected to a wordline WL. A second row of the reference bit circuit 20 includes MTJs 120, 135, 140, and 155 and NFETs 125, 130, 145, and 150. A third row of the reference bit circuit 20 includes MTJs 200, 215, 220, and 235 and NFETs 205, 210, 225, and 230. A fourth row of the reference bit circuit 20 includes the MTJs 280, 295, 300, and 315 and NFETs 285, 290, 305, and 310. Further, a node T1 is connected to the bitlines PBL0 and PBL1, a node T2 is connected to source lines PSL0 and APSL0, and a node T3 is connected to bitlines APBL0 and APBL1. The connections of the bitlines PBL0, PBL1, APBL0, and APBL1 to form nodes T1, T2, and T3 can be done directly through metal lines of through transmission gate switches.

In FIG. 1, the read/write array 30 includes MTJs 75, 90, 95, and 115 which are connected to respective bitlines BL0, BL1, BL2, and BL3 in a first row. The first row of the read/write array 30 also includes NFETs 80, 85, 100, and 105 which are connected to the wordline WL. A second row of the read/write array 30 includes MTJs 160, 175, 180, and 195 and NFETs 165, 170, 185, and 190. A third row of the read/write array 30 includes MTJs 240, 255, 260, and 275 and NFETs 245, 250, 265, and 270. A fourth row of the read/write array 30 includes MTJs 320, 335, 340, and 355 and NFETs 325, 330, 345, and 350.

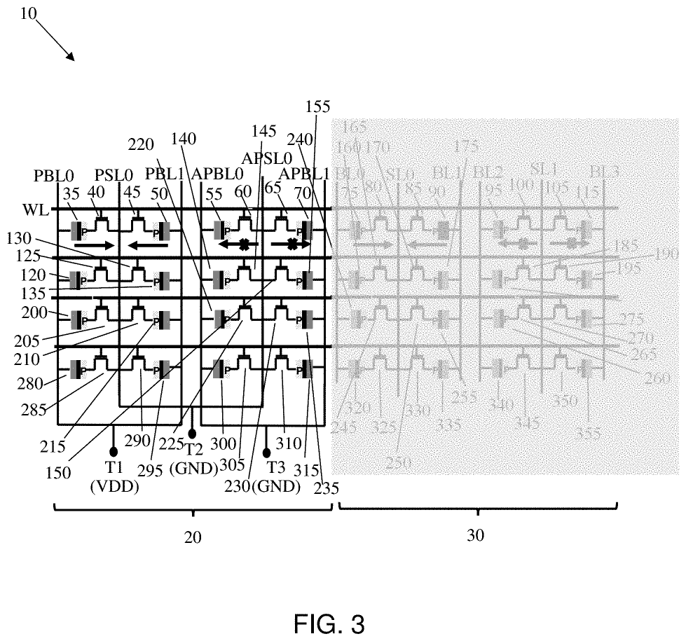

In operation of FIG. 1, the four columns of the reference bit circuit 20 are used for reference bit generation (i.e., a reference resistance value). In particular, the four columns of the reference bit circuit 20 use the wordline WL from the same bitcell as the read/write array 30 to generate the reference bit generation (i.e., a value of ((RP+RAP)/2)). The read/write array 30 is a read/write array which does not require any additional disclosure for one of ordinary skill in the art to have a complete understanding of the present disclosure. The details of the operations of programming and read operations are detailed in the descriptions of FIGS. 3, 4, 5A, and 5B.

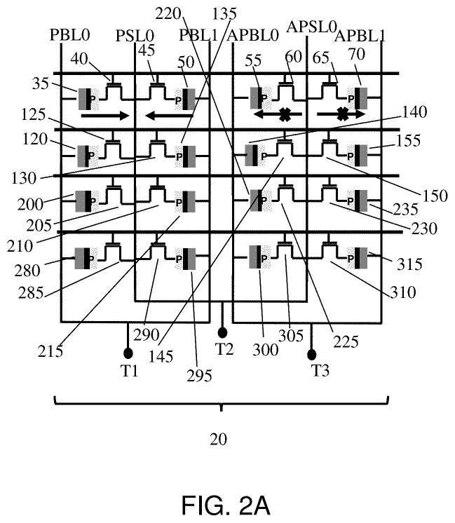

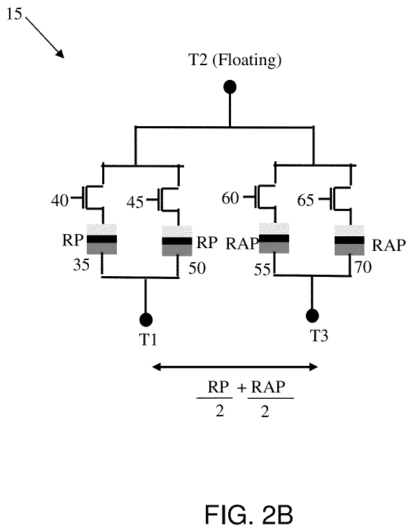

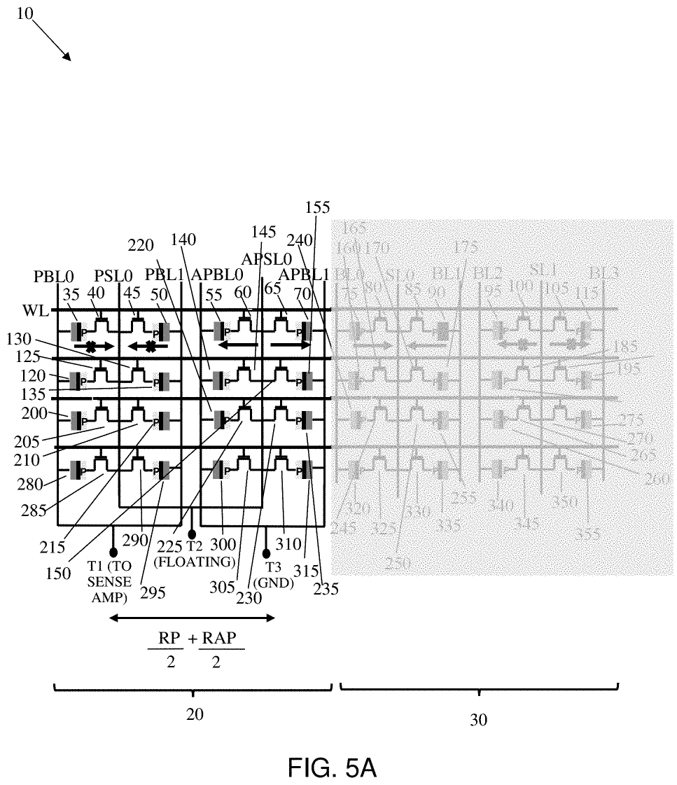

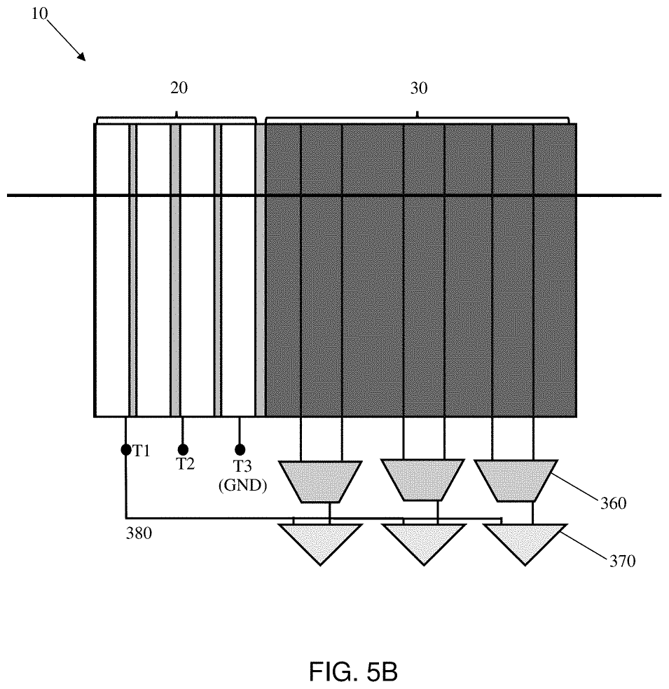

FIG. 2A shows the reference bit circuit 20 of the MRAM structure 10 (similar to FIG. 1). FIG. 2B shows a representation 15 of the reference bit circuit 20 of the MRAM structure 10. In FIG. 2B, the representation 15 of the reference bit circuit 20 of the MRAM structure 10 floats the node T2. Further, in FIG. 2B, RP (parallel resistance) is a low resistance value and RAP (anti-parallel resistance) is a high resistance value. In the representation 15 of FIG. 2B, a midpoint resistance value of (RP/2+RAP/2) is generated for the MRAM sensing/read operation. Further, details of the MRAM sensing/read operation will be described in FIGS. 5A and 5B.

FIG. 3 shows programming of the reference bit circuit in a first cycle of the MRAM structure in accordance with aspects of the present disclosure. In the MRAM structure 10, the read/write array 30 is disabled (shown as shaded area in FIG. 3) in the first cycle so that programming of reference bits can be performed in the reference bit circuit 20. In FIG. 3, the T1 node is set to VDD (i.e., a power supply value), the T2 node is set to GND, and the T3 node is set to GND. As the T2 and T3 nodes are set to GND, no current will flow through the bitlines APBL0 and APBL1 and source line APSL0. Further, as the wordline WL is set to VDD, current flows from the bitlines PBL0, PBL1 toward the source line PSL0 such that a free layer switches to or maintains a parallel resistance (RP) state (i.e., a low resistance value). When the parallel resistance (RP) state is programmed, a logic value of “0” is stored in the MRAM structure 10.

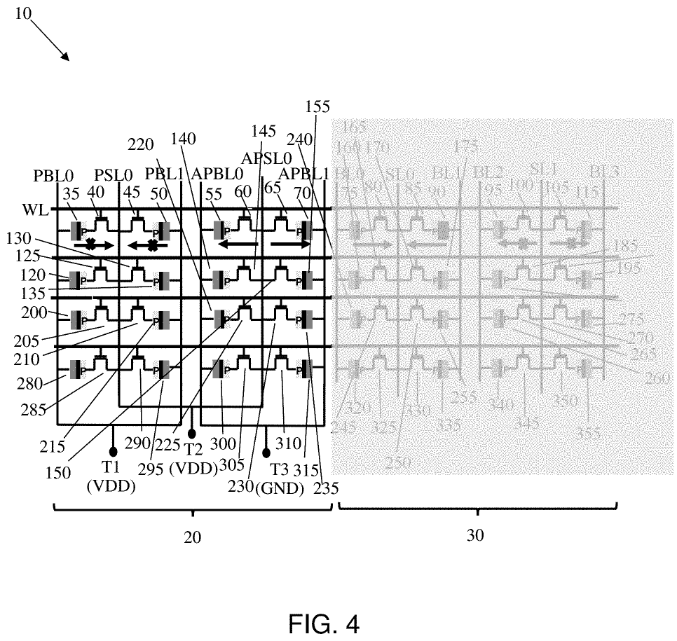

FIG. 4 shows programming of the reference bit circuit in a second cycle of the MRAM structure in accordance with aspects of the present disclosure. In the MRAM structure 10, the read/write array 30 is disabled (shown as shaded area in FIG. 4) in the second cycle so that programming of reference bits can be performed in the reference bit circuit 20. In FIG. 4, the T1 node is set to VDD (i.e., a power supply value), the T2 node is set to VDD, and the T3 node is set to GND. As the T1 and T2 nodes are set to VDD, no current will flow through the bitlines PBL0 and PBL1 and source line PSL0. Further, as the wordline WL is set to VDD, current flows from the source line APSL0 to the bitlines APBL0, APBL1 such that the free layer switches to or maintains an anti-parallel resistance (RAP) state (i.e., a high resistance value). When the anti-parallel resistance (RAP) state is programmed, a logic value of “1” is stored in the MRAM structure 10.

FIG. 5A shows a read operation of the reference bit circuit of the MRAM structure 10 in accordance with aspects of the present disclosure. In the MRAM structure 10, the read/write array 30 is disabled (shown as grayed out in FIG. 5A) so that the read operation can be performed in the reference bit circuit 20. In FIG. 5A, the T2 node is floating and the T3 node is set to GND. As the T2 node is floating and the T3 node is set to GND, no current will flow through the bitlines PBL0 and PBL1 and source line PSL0. Further, as the wordline WL is set to VDD, current flows from the source line APSL0 to the bitlines APBL0, APBL1 such that the free layer switches to or maintains an anti-parallel resistance (RAP) state (i.e., a high resistance value). Further, as a result of the T2 node being floated and the T3 node being sent to GND, the T1 node generates and outputs the reference bit generation (i.e., a resistance value of ((RP/2)+(RAP/2))) to a sense amplifier 370 (see FIG. 5B).

FIG. 5B shows a representation of the read operation of the reference bit circuit of the MRAM structure in accordance with aspects of the present disclosure. In the representation of the read operation of the reference bit circuit 20 of the MRAM structure 10, the read/write array 30 is connected to inputs of a plurality of column multiplexers 360. The column multiplexers 360 select an input from the read/write array 30 and output the selected input to a plurality of sense amplifiers 370. The sense amplifiers 370 also receive the reference bit generation (i.e., a resistance value of ((RP/2)+(RAP/2))) as an input 380 from the T1 node and the T3 node is set to GND. Therefore, the MRAM structure 10 uses the input 380, the column multiplexers 360, and the sense amplifiers 370 to sense (i.e., read) a programmed (i.e., stored) value.

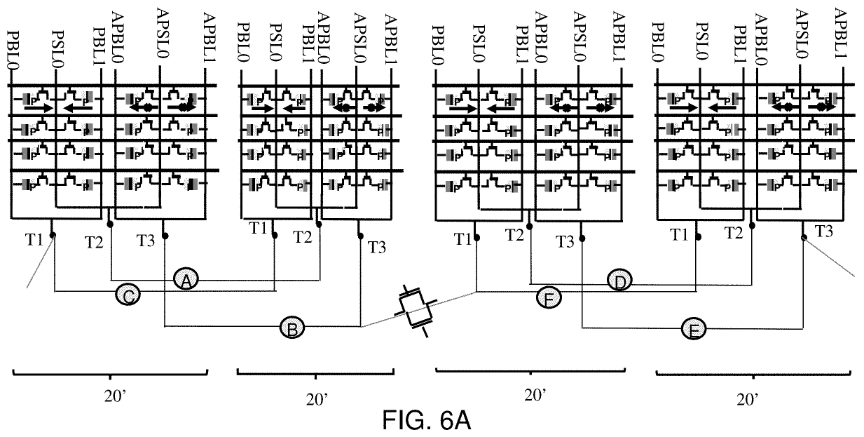

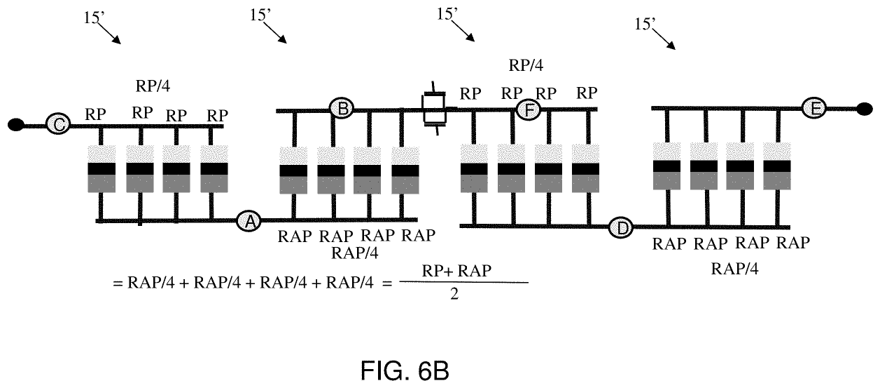

FIG. 6A shows another plurality of reference bit circuits in accordance with aspects of the present disclosure. In FIG. 6A, each of the plurality of reference bit circuits 20′ include the same elements as each of the plurality of reference bit circuits 20 in FIG. 1. In FIG. 6A, each of the plurality of reference bit circuits 20′ are connected together at T1, T2, and T3 nodes. For example, the T1 nodes of the plurality of reference bit circuits 20′ are connected together at points “C” and “F”. The T2 nodes of the plurality of reference bit circuits 20′ are connected together at points “A” and “D”. The T3 nodes of the plurality of reference bit circuits 20′ are connected together at points “B” and “E”. Lastly, one of the plurality of reference bit circuits 20′ has a T3 node which is connected to a T1 node of another one of the plurality of reference bit circuits 20′ (i.e., see the rectangular box with ⊥ at both ends, which is between points “B” and “F”).

FIG. 6B shows a representation of another plurality of reference bit circuits in accordance with aspects of the present disclosure. In FIG. 6B, each representation 15′ of the plurality of reference bit circuits 20′ is connected to another representation 15′ of the plurality of reference bit circuits 20′. For example, the “A” and “C” points are connected to four (4) RP (parallel resistance) elements (i.e., corresponding to MTJs 35 and 50 in FIG. 1). Further, the “A” and “B” points are connected to four (4) RAP (anti-parallel resistance) elements (i.e., corresponding to MTJs 55 and 70 in FIG. 1). The “D” and “F” points are also connected to four (4) RP (parallel resistance) elements (i.e., these correspond to MTJs 35 and 50 in FIG. 1). The “D” and “E” points are also connected to four (4) RAP (anti-parallel resistance) elements (i.e., these correspond to MTJs 55 and 70 in FIG. 1). By using the representation 15 of FIG. 6B, a midpoint resistance value of ((RP+RAP)/2) is generated by using 16 MTJs per row (i.e., RP/4+RAP/4+RP/4+RAP/4=(RP+RAP)/2).

The circuit and the method for row-wise tracking of reference generation for magnetic random access memory (MRAM) of the present disclosure can be manufactured in a number of ways using a number of different tools. In general, though, the methodologies and tools are used to form structures with dimensions in the micrometer and nanometer scale. The methodologies, i.e., technologies, employed to manufacture the circuit and the method for row-wise tracking of reference generation for magnetic random access memory (MRAM) of the present disclosure has been adopted from integrated circuit (IC) technology. For example, the structures are built on wafers and are realized in films of material patterned by photolithographic processes on the top of a wafer. In particular, the fabrication of the circuit and the method for row-wise tracking of reference generation for magnetic random access memory (MRAM) uses three basic building blocks: (i) deposition of thin films of material on a substrate, (ii) applying a patterned mask on top of the films by photolithographic imaging, and (iii) etching the films selectively to the mask.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor. Further, the circuit and the method for logic-in-memory computations of the present disclosure can have wide applicability in high throughput processors for machine learning and artificial intelligence.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A structure comprising a plurality of magnetic random access memory (MRAM) bitcells comprising a first circuit and a second circuit, the second circuit being connected to a same wordline as the first circuit such that the second circuit is configured as a parallel series connection to generate a reference resistance value for sensing,
wherein the first circuit comprises a first bitline connected to a first magnetic tunnel junction (MTJ), the first MTJ is connected to a first transistor, a drain of the first transistor is directly connected to a source of a second transistor, the second transistor is connected to a second MTJ, and the second MTJ is connected to a second bitline, and
a gate of the first transistor and a gate of the second transistor are directly connected to the same wordline.

2. The structure of claim 1, wherein the second circuit comprises a reference bit circuit which comprises a plurality of columns for generating the reference resistance value.

3. The structure of claim 2, wherein the reference bit circuit comprises a true bitcell which is configured to generate the reference resistance value of (RP+RAP)/2 to enable midpoint sensing, wherein RP comprises a parallel resistance and RAP comprises an anti-parallel resistance.

4. (canceled)

5. The structure of claim 1, wherein each of the first transistor and the second transistor comprise a NFET transistor.

6. The structure of claim 1, wherein the reference bit circuit comprises a series combination of a plurality of magnetic tunnel junction (MTJ) bitcells connected in parallel.

7. The structure of claim 2, wherein the reference bit circuit comprises a plurality of reference bits which simultaneously are programmed when an array of the MRAM bitcells is being written.

8. The structure of claim 2, wherein the reference bit circuit is used to generate the reference resistance value during a read operation of (RP+RAP)/2 to enable midpoint sensing, wherein RP comprises a parallel resistance and RAP comprises an anti-parallel resistance.

9. The structure of claim 2, wherein the reference bit circuit generates the reference resistance value from the same wordline as the first circuit, and the first circuit comprises a read/write array circuit.

10. A circuit, comprising:
a reference bit circuit which comprises a plurality of first columns for generating a reference resistance value; and
a read/write array circuit which comprises a plurality of second columns for performing at least one of a read operation and a write operation,
wherein the reference bit circuit comprises a first bitline connected to a first magnetic tunnel junction (MTJ), the first MTJ is connected to a first transistor, a drain of the first transistor is directly connected to a source of a second transistor, the second transistor is connected to a second MTJ, and the second MTJ is connected to a second bitline, and
a gate of the first transistor and a gate of the second transistor are directly connected to a same wordline.

11. (canceled)

12. The circuit of claim 10, wherein each of the first transistor and the second transistor comprise a NFET transistor.

13. The circuit of claim 10, wherein the reference bit circuit comprises a series combination of a plurality of magnetic tunnel junction (MTJ) bitcells connected in parallel.

14. The circuit of claim 10, wherein the reference bit circuit comprises a plurality of reference bits which simultaneously are programmed when an array is being written.

15. The circuit of claim 10, wherein the reference bit circuit is used to generate the reference resistance value during a read operation of (RP+RAP)/2 to enable midpoint sensing, wherein RP comprises a parallel resistance and RAP comprises an anti-parallel resistance.

16. The circuit of claim 10, wherein the reference bit circuit generates the reference resistance value from the same wordline as a wordline of the read/write array circuit.

17. A method, comprising:
programming a plurality of reference bits in a reference bit circuit which is connected to a read/write array circuit; and
sensing the plurality of reference bits using at least one sense amplifier which is connected to an output of the reference bit circuit,
wherein the reference bit circuit comprises a first bitline connected to a first magnetic tunnel junction (MTJ), the first MTJ is connected to a first transistor, a drain of the first transistor is directly connected to a source of a second transistor, the second transistor is connected to a second MTJ, and the second MTJ is connected to a second bitline, and
a gate of the first transistor and a gate of the second transistor are directly connected to a same wordline.

18. The method of claim 17, wherein the plurality of reference bits is programmed in the reference bit circuit using the same wordline as a wordline of the read/write array circuit.

19. The method of claim 17, wherein the reference bit circuit comprises a plurality of rows and each of the rows comprise a plurality of magnetic tunnel junctions (MTJs).

20. The method of claim 19, wherein the plurality of MTJs comprise sixteen MTJs connected in parallel in each of the rows of the reference bit circuit.

21. The structure of claim 1, wherein the second circuit comprises a third bitline connected to a third MTJ, and the third MTJ is connected to a fourth transistor.

22. The structure of claim 21, wherein the fourth transistor is connected to a fourth MTJ, and the fourth MTJ is connected to a fourth bitline.
